(19) United States
(12) Patent Application Publication
(10) Pub. No.: US 2026/0074716 A1
(43) Pub. Date: Mar. 12, 2026

(54) POWER-IMBALANCED MULTI-LEVEL DECODING METHOD AND SYSTEM FOR SPARSE CODE MULTIPLE ACCESS

(71) Applicant: Guangdong University of Technology, Guangzhou (CN)

(72) Inventors: Yi FANG, Guangzhou (CN); Jiaqin CHEN, Guangzhou (CN); Zhaojie YANG, Guangzhou (CN); Jia ZHAN, Guangzhou (CN); Dingfei MA, Guangzhou (CN); Yunye LI, Guangzhou (CN)

(21) Appl. No.: 19/393,076

(22) Filed: Nov. 18, 2025

(30) Foreign Application Priority Data
Jan. 16, 2025 (CN) 202510069692.3

(51) Int. Cl. H03M 13/27; H03M 13/39

(52) U.S. Cl. CPC H03M 13/2735; H03M 13/3927

(57) ABSTRACT

A power-imbalanced multi-level decoding method for sparse code multiple access includes: encoded bits of all users are mapped to multi-dimensional sparse codewords through predetermined codebooks; a factor graph matrix is constructed using the predetermined codebooks, all users are classified according to the factor graph matrix under predetermined constraints to determine Z levels; based on a predetermined total transmission power, a progressive multi-level power optimization algorithm is employed to perform power-imbalanced allocation for all users according to the Z levels, thereby determining a locally optimal power vector; transmission signals corresponding to the multi-dimensional sparse codewords are transmitted according to the locally optimal power vector; SCMA detection and power-oriented decoding are sequentially performed for users each level, and outputs decoded bit sequences for the L levels.

### CROSS-REFERENCE TO RELATED APPLICATIONS

This application claims the benefit of priority from Chinese Patent Application No. 202510069692.3, filed on Jan. 16, 2025. The content of the aforementioned application, including any intervening amendments made thereto, is incorporated herein by reference in its entirety.

### TECHNICAL FIELD

This application relates to communication technology, and more particularly to a power-imbalanced multi-level decoding (PI-MLD) method and system for sparse code multiple access (SCMA).

### BACKGROUND

With the rapid development of mobile communication technologies and the proliferation of smart devices, spectrum resources are becoming increasingly scarce. To address this challenge, the fifth generation of mobile communication systems (5G) has introduced Non-Orthogonal Multiple Access (NOMA) as a multiple access technique, among which SCMA has attracted significant attention. Firstly, SCMA offers significant advantages in spectral efficiency, interference resistance, and support for massive connectivity. SCMA enables more users to access limited spectrum resources, meeting the massive connection requirements of 5G to alleviate spectrum scarcity. Secondly, SCMA exhibits strong interference resistance, maintaining stable communication quality even in high-interference environments. Finally, SCMA supports massive connectivity, fulfilling the demands of 5G application scenarios such as the Internet of Things (IoT) and large-scale sensor networks.

For SCMA systems, channel coding can effectively mitigate inter-user interference and enhance data transmission reliability. A structured Low-Density Parity-Check (LDPC) code known as Protograph LDPC (PLDPC) is considered a relatively ideal channel coding scheme for SCMA systems. A block diagram of an uplink PLDPC-coded SCMA system is shown in FIG. 1. Specifically, the uplink PLDPC-coded SCMA system including J independent users and K orthogonal resources is considered. Each user independently performs PLDPC coding and is equipped with a single antenna. To achieve overloaded multi-user communication, the condition J>K is imposed, and the overload factor is defined as λ=J/K>1. Each user can only occupy dᵥ<K resources for communication transmission, while each resource is simultaneously shared by d_{f}<J users. Given an SCMA system with J users and K resources, a corresponding factor graph matrix F_{K×J} can clearly reveal the allocation relationship between users and resources. At the transmitter, the information bit sequence of the user j is denoted as bⱼ={b₁, b₂, . . . , bₖ}, where je {1, 2, . . . , J}. Firstly, the information bit sequence of the user is fed to a PLDPC encoder to obtain an encoded bit sequence cⱼ={c₁, c₂, . . . , cₙ}, where the code rate is denoted as R=k/n. Then, the encoded bit sequence is fed to a bit-level random interleaver π to produce an interleaved encoded bit sequence ĉⱼ={ĉ₁, ĉ₂, . . . , ĉₙ}. Subsequently, every m=log₂M bits extracted from ĉⱼ are mapped to a K-dimensional complex symbol Xⱼ=[x_{1,j}, x_{2,j}, . . . , x_{K,j}]^{T} by the SCMA mapper, where xⱼ is one of the column vectors of the SCMA codebook with cardinality |X^{j}|=M, and M represents a modulation order. Due to the sparsity of SCMA, only dᵥ elements in a sparse codeword xⱼ are non-zero, while the K−dᵥ remaining elements are ‘0’ element. Then, the K-dimensional sparse codewords from all users are superimposed as a transmission signal. After the transmission signal propagates through a Rayleigh fading channel, the received signal vector y=[y₁, y₂, . . . , y_{K}]^{T} at the receiver is expressed as in formula

$$y = {\sum }_{j = 1}^{J} diag ( {h}_{j} ) {x}_{j} + n ,$$

where nⱼ=[h_{1,j}, h_{2,j}, . . . , h_{K,j}]^{T} denotes the channel gain for the user j, n□CN(0, N₀I) represents K×I additive complex Gaussian white noise vector, and N₀ is the noise power spectral density. At the SCMA detector, the log-domain Message Passing Algorithm (log-MPA) can be exploited to compute the interleaved log-likelihood ratio (LLR) sequence

$${L}_{j}^{in}$$

corresponding to the interleaved encoded bit sequence of the user j. After processing by the deinterleaver, the LLRs sequence

$${L}_{j}^{de}$$

is obtained. Then, this sequence

$${L}_{j}^{d e}$$

is processed by the PLDPC decoder using the belief propagation (BP) algorithm, and the decoded bit sequence for each user can be yield.

However, in the aforementioned traditional PLDPC-encoded SCMA scheme, the transmission power is equally allocated to each user during resource allocation, and the decoding processes for different users are independent of each other, which fails to effectively eliminate inter-user interference, resulting in a high bit-error-rate (BER) in the SCMA system.

### SUMMARY

In view of the deficiencies in the prior art, this application provides a PI-MLD method and system for SCMA, which addresses the technical problem in traditional PLDPC-coded SCMA schemes where equal transmission power allocation for each user during resource allocation and independent decoding processes for different users fail to effectively eliminate inter-user interference, consequently resulting in a high BER in the SCMA system.

Technical solutions of the present disclosure are described as follows.

In a first aspect, this application provides a PI-MLD method for SCMA, comprising:
(a) generating to-be-encoded information bits of all users at a transmitter, and encoding the to-be-encoded information bits via a PLDPC encoder; mapping information bits (namely encoded information bits or encoded bits) of all users to multi-dimensional sparse codewords via predetermined codebooks;
(b) at the transmitter, constructing a factor graph matrix using each predetermined codebook, and classifying all users into L levels based on the factor graph matrix under a predetermined constraint, wherein L is a positive integer greater than 1;
(c) based on a predetermined total transmission power, performing, by the transmitter, a power-imbalanced allocation (PIA) for all users according to the Z levels using a progressive multi-level power optimization algorithm to determine a locally optimal power vector;
(d) transmitting a transmission signal corresponding to the multi-dimensional sparse codewords according to the locally optimal power vector; and
(e) after propagating through a Rayleigh fading channel, sequentially performing, by the receiver, a SCMA detection and a power-oriented decoding for users of each level, and outputting decoded bit sequences for the Z levels.

In an embodiment, the predetermined constraint comprises: the number of users in each level must be equal; and each resource within each level is multiplexed, and each resource is multiplexed by the same number of users.

In an embodiment, the step (c) comprises:
(c1) after the transmitter performs an equal-power initialization on an initial power of each user based on the predetermined total transmission power, and the transmission signal propagates through the Rayleigh channel fading, calculating mutual information based on the initial power of each user using a protograph extrinsic information transfer (PEXIT) algorithm at the receiver;
(c2) performing a mean operation on the mutual information to output an initial average mutual information (AMI), and assigning the initial AMI to an old AMI;
(c3) when performing a (i=1)-th power allocation according to a power unit step size of 8, decreasing an initial power of a (L+1−i)-th level by δ×(┌L/2┐−i) and increasing an initial power of an i-th level by δ×(┌L/2┐−i), so as to determine a monotonic initialization power of the (L+1−i)-th level and a monotonic initialization power of the i-th level; wherein δ is a positive number;
(c4) based on the PEXIT algorithm, determining monotonic initialization AMI corresponding to the (L+1−i)-th level and the i-th level using the monotonic initialization power of the (L+1−i)-th level and the monotonic initialization power of the i-th level;
(c5) when the monotonic initialization AMI is greater than the old AMI, assigning the monotonic initialization AMI to the old AMI;
(c6) decreasing the monotonic initialization power of the (L+1−i)-th level by δ; increasing the monotonic initialization power of the i-th level by δ; and determining a locally optimized power of the (L+1−i)-th level and a locally optimized power of the i-th level, and counting a number of allocations k;
(c7) based on the PEXIT algorithm, determining locally optimized AMI corresponding to the (L+1−i)-th level and the i-th level using the locally optimized power of the (L+1−i)-th level and the locally optimized power of the i-th level; and
(c8) when the locally optimized AMI is less than or equal to the old AMI, taking a locally optimized power of a (k−1)-th allocation as a locally optimal power of the (L+1−i)-th level and the i-th level;
wherein if Z is an even number, performing a next power allocation according to the power unit step size of δ until └L/2 ┘ power allocations are performed, and determine locally optimal powers of the L levels and forming a locally optimal power vector; and
if L is an odd number, performing a next power allocation according to the power unit step size of 8 until └L/2 ┘ power allocations are performed; decreasing an initial power of a ┌L/2┐-th level by δ, and increasing a locally optimal power of a first level by δ; outputting a monotonic initialization power of the ┌L/2┐-th level and a new monotonic initialization power of the first level to determine a corresponding locally optimal power, and forming the locally optimal power vector from the locally optimal power of the Z levels.

In an embodiment, the PI-MLD method further comprises:
when the locally optimized AMI is greater than the old AMI, determining whether the number of allocations k is less than a predetermined maximum iteration count └1/δ┘−i;
if yes, setting the locally optimized power as a new monotonic initialization power and setting the locally optimized AMI as a new old AMI, decreasing the monotonic initialization power of the (L+1−i)-th level by δ, and increasing the monotonic initialization power of the i-th level by δ, until the locally optimized AMI is less than or equal to the new old AMI; and
if no, a locally optimized power at the k-th allocation is taken as a locally optimal power of the (L+1−i)-th level and the i-th level.

In an embodiment, the step (e) comprises:
(e1) at the receiver, calculating initial LLR sequences for the received signal corresponding to the transmission signal associated with each level;
(e2) at the SCMA detector, calculating extrinsic interleaved LLR sequences using a log-MPA based on the initial LLR sequences;
(e3) at the PLDPC decoder, deinterleaving the extrinsic interleaved LLR sequences of the first level, and performing a decoding using a belief propagation algorithm to output decoded bit sequences and first-level extrinsic LLR sequences of the first level;
(e4) interleaving the first-level extrinsic LLR sequences to obtain new initial LLR sequences of the first level, and calculating new extrinsic interleaved LLR sequences using the log-MPA based on each new initial LLR sequence in the SCMA detector; and
(e5) deinterleaving extrinsic interleaved LLR sequences of a next level, and performing decoding using the belief propagation algorithm, until decoded bits of the L levels are output and formed into the decoded bit sequences.

In an embodiment, the step (e1) comprises:
performing a logarithmic operation on a reciprocal of a modulation order of the transmission signal associated with each level at the receiver to determine the initial LLR for the received signal corresponding to the transmission signal; and
constructing the initial LLR sequences using each initial LLR.

In a second aspect, this application provides a PI-MLD system for SCMA, comprising:
a transmitter;
a Rayleigh fading channel; and
a receiver;
the transmitter is configured for generating to-be-encoded information bits of all users, and mapping encoded bits from all users to multi-dimensional sparse codewords via predetermined codebooks; constructing a factor graph matrix using each predetermined codebook, and classifying all users into L levels based on the factor graph matrix under a predetermined constraint, wherein L is a positive integer greater than 1; based on a predetermined total transmission power, performing PIA for all users according to the L levels using a progressive multi-level power optimization algorithm to determine a locally optimal power vector;
the Rayleigh fading channel is configured for transmitting transmission signals corresponding to the multi-dimensional sparse codewords according to the locally optimal power vector; and
the receiver is configured for sequentially performing a SCMA detection and a power-oriented decoding for users of each level, and outputting decoded bit sequences of the L levels.

In a third aspect, this application provides a computer device comprising a memory and a processor. The memory stores a computer program. When executed by the processor, the computer program performs the steps of the PI-MLD method described above.

In a fourth aspect, this application provides a computer-readable storage medium storing computer program/instructions. When executed, the computer program instruction implements the PI-MLD method described above.

In a fifth aspect, this application provides a computer program product comprising computer programs/instructions. When executed by a processor, the computer programs/instructions implement the PI-MLD method described above.

Compared to the prior art, the present disclosure has the following beneficial effects.

A PI-MLD method for SCMA provided in this application includes the following steps. At a transmitter, information bits to be encoded for all users are generated and encoded by a PLDPC encoder, and encoded bits from all users are mapped to multi-dimensional sparse codewords through predetermined codebooks. A factor graph matrix is constructed using predetermined codebooks. All users are classified according to the factor graph matrix under predetermined constraints to determine L levels, where L is a positive integer greater than 1. Based on the predetermined total transmission power, a progressive multi-level power optimization algorithm is employed to perform PIA for all users according to the L levels, thereby determining a locally optimal power vector. Transmission signals corresponding to the multi-dimensional sparse codewords are transmitted according to the locally optimal power vector. After the signal propagates through a Rayleigh fading channel, the receiver sequentially performs SCMA detection and power-oriented decoding for users of each level, and outputs decoded bit sequences for the L levels. The factor graph matrix clearly reveals the mapping relationship between users and resources, and thus level classification of all users can be achieved according to the factor graph matrix by imposing predetermined constraints. Under the premise of maintaining constant total transmission power, PIA is performed for the users of each level to obtain a locally optimal power vector. By leveraging the power imbalance characteristics, power-oriented decoding is implemented. Thus, the combination of power imbalance and multi-level decoding helps to further eliminate inter-user interference, thereby reducing the BER of the SCMA system.

### BRIEF DESCRIPTION OF THE DRAWINGS

In order to illustrate the technical solution in the embodiments of the present disclosure or in the prior art more clearly, the drawings required in the description of the embodiments or the prior art will be briefly described below. Obviously, presented in the drawings are merely some embodiments of the present disclosure, which are not intended to limit the disclosure. For those skilled in the art, other drawings may also be obtained according to the drawings provided herein without paying creative efforts.

FIG. 1 is a block diagram of a traditional PLDPC-encoded SCMA system;

FIG. 2 is a flowchart illustrating steps of a PI-MLD method for SCMA according to an embodiment of the present disclosure;

FIG. 3 is a block diagram of a power-oriented multi-level decoding (MLD) receiver according to an embodiment of the present disclosure;

FIG. 4 is a graph showing average bit error rate (AVE-BER) curves of a PI-MLD-SCMA system and a traditional system in simulation tests according to an embodiment of the present disclosure; and

FIG. 5 is a structural block diagram of the PI-MLD-SCMA system according to an embodiment of the present disclosure.

### DETAILED DESCRIPTION OF EMBODIMENTS

A PI-MLD method and system for SCMA provided herein is used to solve the technical problems in traditional PLDPC-encoded SCMA schemes where equal transmission power allocation for each user during resource allocation and independent decoding processes for different users fail to effectively eliminate inter-user interference, consequently resulting in a high BER in the SCMA system.

The technical solutions of the disclosure will be described in detail below in combination with the drawings in the embodiments to make the technical solutions, objects and advantages of the disclosure clearer. Obviously, described below are merely some embodiments of the disclosure, which are not intended to limit the disclosure. For those skilled in the art, other embodiments obtained based on these embodiments without paying creative efforts should fall within the scope of the disclosure defined by the appended claims.

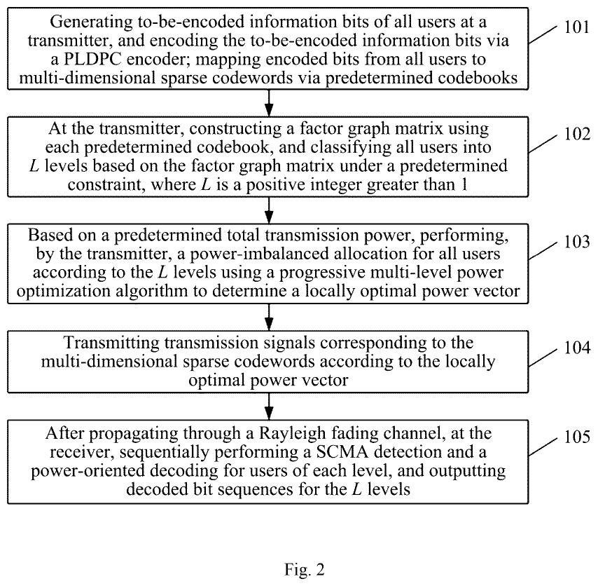

Referring to FIG. 2, a flowchart illustrating the steps of a PI-MLD method for SCMA is shown.

The PI-MLD method includes the following steps 101-105.

### Step 101

At a transmitter, information bits to be encoded for all users are generated and encoded by a PLDPC encoder, and encoded bits of all users are mapped to multi-dimensional sparse codewords through predetermined codebooks.

It should be noted that, in the transmitter of the SCMA system, the information bits of the users processed using PLDPC encoding and are then mapped to sparse multi-dimensional complex constellation points (namely multi-dimensional sparse codewords). These multi-dimensional sparse codewords are selected from pre-designed codebooks, with each user having its own codebook. This direct mapping approach enhances spectral efficiency and achieves considerable constellation shaping gain. Furthermore, these codewords are sparse, meaning each codeword from every user occupies only a portion of resources for communication data transmission. In an embodiment, the resources can be different physical frequencies.

### Step 102

A factor graph matrix is constructed using the predetermined codebooks. The predetermined codebooks are existing codebooks. All users are classified according to the factor graph matrix under predetermined constraints to determine L levels, where L is a positive integer greater than 1.

The predetermined constraints include: the number of users contained in each level must be equal; and within each level, all resources are multiplexed, and each resource is multiplexed by an identical number of users.

It should be noted that for a given K×J SCMA system, the corresponding factor graph matrix F_{K×J} is utilized for level classification of all users, where K represents the number of orthogonal resources, and J represents the number of users. For example, factor graph matrices corresponding to a 4×6 SCMA system and a 6×9 SCMA system are respectively given as follows:

$${F}_{4 \times 6} = [ \begin{matrix}0 & 1 & 1 & 0 & 1 & 0 \\ 1 & 0 & 1 & 0 & 0 & 1 \\ 0 & 1 & 0 & 1 & 0 & 1 \\ 1 & 0 & 0 & 1 & 1 & 0\end{matrix} ] , {F}_{6 \times 9} = [ \begin{matrix}0 & 0 & 1 & 1 & 0 & 0 & 0 & 1 & 0 \\ 0 & 1 & 0 & 1 & 0 & 0 & 1 & 0 & 0 \\ 0 & 0 & 1 & 0 & 1 & 0 & 1 & 0 & 0 \\ 1 & 0 & 0 & 0 & 0 & 1 & 0 & 1 & 0 \\ 1 & 0 & 0 & 0 & 1 & 0 & 0 & 0 & 1 \\ 0 & 1 & 0 & 0 & 0 & 1 & 0 & 0 & 1\end{matrix} ]$$

In one factor graph matrix, each row vector represents one orthogonal resource, and each column vector represents one independent user. In the first column of the matrix, two elements ‘1’ indicate that user 1 occupies the second resource and the fourth resource for communication transmission, respectively, while ‘0’ elements indicate non-occupancy. The number of resources de occupied by a single user is 2, that is dᵥ=2, and the number of times de that a single resource is multiplexed by users is 3, that is d_{f}=3. Similarly, in the second column of the matrix F_{6×9}, two elements ‘1’ indicate that user 2 occupies the second resource and the sixth resource for communication transmission, respectively.

Before level classification, the following user constraints are imposed: (i) For one given SCMA system, all users can be classified into L levels in total, and the number of users contained in each level must be equal, namely J/L users; (ii) For one given SCMA system, within each level, all K resources are multiplexed, and each resource is multiplexed by the same number of users.

Based on the user constraints (i) and (ii), typical examples for level classification of SCMA system are provided as follows. For one 4×6 SCMA system with the factor graph matrix of F_{4×6}, the 6 users can be classified into 3 levels according to the user constraints, with users 1 and 2 assigned to one level, users 3 and 4 to one level, and users 5 and 6 to one level. For one 6×9 SCMA system with the factor graph matrix of F_{6×9}, all users can be classified into 3 levels, with users 1, 2, and 3 assigned to one level, users 4, 5, and 6 to one level, and users 7, 8, and 9 to one level. Additionally, the user constraints may also include (iii): for an SCMA system with an overload factor of λ=J/K, systems with the same overload factor can be classified into the same number of levels. For example, both the 4×6 SCMA system and the 6×9 SCMA system have an overload factor of 1.5, so the 6×9 SCMA system can adopt the same number of levels as the 4×6 SCMA system. Typical level classifications of SCMA systems are shown in Table 1.

TABLE 1
Typical level classifications of SCMA Systems

| SCMA system (K | Overload | The number of | The number of |
|---|---|---|---|
| resources × J users) | factor λ | levels L | users on per level |
| 5 × 10 | 2 | 2 | 5 |
| 4 × 6, 6 × 9, 8 × 12 | 1.5 | 3 | 2, 3, 4 |
| 6 × 8, 9 × 12 | 1.33 | 4 | 2, 3 |

### Step 103

Based on the predetermined total transmission power, a progressive multi-level power optimization algorithm is employed to perform PIA for all users according to the L levels, thereby determining a locally optimal power vector.

Step 103 includes the following sub-steps.

After performing equal-power initialization of the initial power of each user based on the predetermined total transmission power, mutual information is calculated for each user based on their respective initial power using a PEXIT algorithm.

A mean operation is performed on the mutual information to output an initial AMI, and the initial AMI is assigned to an old AMI.

When performing the (i=1)-th power allocation according to a power unit step size of 8, the initial power of the (L+1−i)-th level is decreased by δ×([L/2]−i), and the initial power of the i-th level is increased by δ×([L/2]−i), so as to determine a monotonic initialization power of the (L+1−i)-th level and a monotonic initialization power of the i-th level; where δ is a positive number. └ ┘ denotes the floor function, and ┌ ┐ denotes the ceiling function.

Based on the PEXIT algorithm, monotonic initialization AMI corresponding to the (L+1−i)-th level and the i-th level is determined using the monotonic initialization powers of the (L+1−i)-th level and the i-th level.

When the monotonic initialization AMI is greater than the old AMI, the monotonic initialization AMI is assigned to the old AMI.

The monotonic initialization power of the (L+1−i)-th level is decreased by δ, and the monotonic initialization power of the i-th level is increased by δ, thereby determining locally optimized powers of the (L+1−i)-th level and the i-th level and counting a number of allocations k.

Based on the PEXIT algorithm, locally optimized AMI corresponding to the (L+1−i)-th level and the i-th level is determined using the locally optimized power of the (L+1−i)-th level and the locally optimized power of the i-th level.

When the locally optimized AMI is less than or equal to the old AMI, the locally optimized power of the (k−1)-th allocation is taken as the locally optimal powers of the (L+1−i)-th level and the i-th level.

If L is an even number, a next power allocation is performed according to the power unit step size of 8 until └L/2┘ power allocations are performed, thereby determining the locally optimal powers of the L levels and forming a locally optimal power vector.

If L is an odd number, a next power allocation is performed according to the power unit step size of 8 until └L/2┘ power allocations are performed. Then, an initial power of a ┌L/2┐-th level is decreased by δ, and a locally optimal power of a first level is increased by δ. The monotonic initialization power of the ┌L/2┐-th level and a new monotonic initialization power of the first level are output to determine a corresponding locally optimal power, and forming the locally optimal power vector from the locally optimal powers of the L levels.

Additionally, when the monotonic initialization AMI is less than or equal to the old AMI, the monotonic initialization power is adopted as the locally optimal power for both the (L+1−i)-th level and the i-th level.

Additionally, when the locally optimized AMI is greater than the old AMI, it is determined whether the number of allocations k is less than the maximum iteration count └1/δ┘−i.

If yes (the number of allocations k is less than the maximum iteration count └1/δ┘−i), the locally optimized power is set as a new monotonic initialization power, and the locally optimized AMI is set as a new old AMI. The monotonic initialization power of the (L+1−i)-th level is decreased by δ, and the monotonic initialization power of the i-th level is increased by δ, until the locally optimized AMI is less than or equal to the new old AMI.

If no (the number of allocations k is not less than the maximum iteration count └1/δ┘−i), the locally optimized power at the k-th allocation is taken as the locally optimal powers of the (L+1−i)-th level and the i-th level.

It should be noted that, after completing the level classification of all users in the SCMA system, we propose the progressive multi-level power optimization algorithm to implement PIA for each level. With the aid of the PEXIT algorithm—a highly effective tool for system performance analysis, the convergence behavior of the AMI of the users is analyzed to determine whether the PIA scheme has reached a locally optimal state.

Before introducing the progressive multi-level power optimization algorithm, the following five power constraints are proposed.

(i) Under the premise that the predetermined total transmission power of the entire SCMA system remains unchanged, the power of each level is normalized to equal power (i.e., the power of all users is set to 1).

(ii) Transmission powers of different users within the same level are equal, whereas the transmission power of different users across different levels is unequal.

(iii) Assuming one SCMA system includes J users and K resources with L levels, the initial power vector corresponding to all levels is p=[p₁, p₂, . . . , p_{L}]. Then, L elements of the locally optimal power vector p₀=[p_{o,1}, p_{o,2}, . . . , p_{o,L}] must satisfy p_{o,1}>p_{o,2}>, . . . , >p_{o,L}>0, and p_{o,n}≠1, where n=1, 2, . . . , L.

(iv) When L is even, the number of levels with low power (power <1) equals the number of levels with high power (power >1), which is └L/2 ┘. When L is odd, the number of levels with low power exceeds the number of levels with high power by one, i.e., the number of the levels with low power is ┌L/2┐.

(v) The minimum power unit step size for PIA is set to δ=0.025. It should be understood that the power unit step size can be adaptively adjusted. It is noted that prior to implementing PIA, all levels may be arbitrarily ordered. The pseudocode of the progressive multi-level power optimization algorithm is shown in Table 2.

TABLE 2
Pseudocode for Progressive Multi-level Power Optimization Algorithm
Progressive Multi-level Power Optimization Algorithm

| | |
|---|---|
| 1 | Input: Initialization parameters: the number of levels L, pₙ=1, n∈{1, |
| | 2, ..., L}, δ=0.025, calculating initial value I_{A} of AMI using PEXIT |
| | algorithm, I_{A,old} = I_{A}. |
| 2 | for i=1 to └L / 2┘ do |
| 3 | for k=1 to └1/δ┘−i do |
| 4 | if i=1 or pᵢ < (pᵢ₋₁−δ) then |
| 5 | p_{L-i+1}= p_{L-i+1}−δ; pᵢ= pᵢ +δ; |
| 6 | Calculating new AMI I_{A} using PEXIT algorithm |
| 7 | if pᵢ≤1+ δ×(└L / 2┘−i) then |
| 8 | continue; |
| 9 | end if |
| 10 | if I_{A} > I_{A,old} then |
| 11 | I_{A,old} = I_{A}; |
| 12 | else |
| 13 | p_{L-i+1}= p_{L-i+1}+δ; pᵢ= pᵢ −δ; |
| 14 | break; |
| 15 | end if |
| 16 | end if |
| 17 | end for |
| 18 | end for |
| 19 | If L is odd, then |
| 20 | Executing steps 7-17 of Algorithm 1 on p_{└L/2┘} and p₁, while |
| | maintaining p_{└L/2┘}> p _{└L/2┘+1}. |
| 21 | End if |
| 22 | Output: Locally optimal power vector Pₒ =[p_{o,1}, p_{o,2},..., p_{o,L}]. |

As shown in Table 2, each power allocation operation involves two levels. During each power allocation operation, the power of other levels remains unchanged. Performing power allocation operation on one level means applying the same power allocation operation to all users within that level. For example, during the (i=1)-th power allocation operation, power allocation operation is performed on the initial power P_{L} of the last level (the L-th level) and the initial power P₁ of the first level. When L is even, a total of └L/2 ┘ power allocation operations are performed, where i=1, 2, . . . , └L/2┘ denotes the i-th power allocation operation. When L is odd, a total of ┌L/2┐ power allocation operations are performed, where i=1, 2, . . . , ┌L/2┐ denotes the i-th power allocation operation. The detailed procedure of the progressive multi-level power optimization algorithm is as follows.

### Step 1

The initial power of all levels is initialized to 1, i.e., pₙ=1, where n∈{1, 2, . . . , L}. The mutual information (MI) is calculated by their respective initial power of each user using the PEXIT algorithm. Then, the MI values across all users are averaged to obtain the initial AMI I_{A}. The old AMI is initialized, and I_{A,old}=I_{A}, so as to store the value of I_{A}.

### Step 2

Assuming that this is the i-th power allocation operation, the initial power P_{L+1-i} of the (L+1−i)-th level is decreased by δ×(┌L/2┐−i), and the power pᵢ of the i-th level is simultaneously increased by the same amount δ×(┌L/2┐−i), thereby determining the corresponding monotonic initialization power. This ensures the monotonically decreasing characteristic of the power constraint (iii). Taking i=1 (the first power allocation operation) as an example, the initial power p_{L} of the L-th level is first decreased by δ×(┌L/2┐−1) to obtain the corresponding monotonic initialization power, while the power p₁ of the first level is increased by δ×(┌L/2┐−1) to obtain the corresponding monotonic initialization power. The PEXIT algorithm is used to calculate the new I_{A}—i.e., the monotonic initialization AMI—based on the monotonic initialization powers of the L-th level and the first level, along with the initial power of the remaining levels. Then, the process proceeds to step 4. It should be noted that, to simplify the algorithm flow, the calculation of the monotonic initialization AMI in step 2 may be omitted, and the process may directly proceed to execute step 3.

### Step 3

The monotonic initialization power of the (L+1−i)-th level is further decreased by δ, while the monotonic initialization power of the i-th level is increased by the same δ, obtaining the corresponding locally optimized power. The new I_{A}, referred to as the locally optimized AMI, is then calculated using the PEXIT algorithm based on the power of each user, and the number of allocations k is recorded.

### Step 4

The locally optimized AMI I_{A} is compared with the old AMI I_{A,old}. If I_{A}>I_{A,old}, the value of the monotonic initialization AMI or the locally optimized AMI I_{A} is assigned to the old AMI I_{A,old}. Then, step 3 is repeated until I_{A}≤I_{A,old} is satisfied.

If the monotonic initialization AMI I_{A} calculated in step 2 is less than or equal to the old AMI I_{A,old}, the monotonic initialization power allocated in step 2 is directly taken as the locally optimal power for the (L+1−i)-th and i-th levels.

Assuming that after performing the k-th iterations of step 3 on the monotonic initialization powers of the (L+1−i)-th level and the i-th level, if the condition (I_{A}≤I_{A,old}) is satisfied, the power allocation from the (k−1)-th iteration of step 3 is selected. This is because after the (k−1)-th iteration, the AMI value I_{A} has reached the maximum, proving that the power allocation between p_{L} and pᵢ has reached a local optimum. At this point, combining steps 2 to 4, the values obtained in the i-th power allocation operation are: the power of the (L+1−i)-th level is p_{o,L+1-i}=1−δ×(k−1)−δ×(┌L/2┐−i), and the power of the i-th level is p_{o,i}=1+δ×(k−1)+δ×(┌L/2┐−i). Taking i=1 as an example, the power of the L-th level is p_{o,L}=1−δ×(k−1)−δ×(┌L/2┐−1), and the power of the first level is p_{o,1}=1+δ×(k−1)+δ×(┌L/2┐−1).

If after performing the k-th iteration of step 3, the condition (I_{A}>I_{A,old}) still holds, the power allocation from the k-th iteration of step 3 is adopted. It should be noted that the value of k may vary in the i-th power allocation operation. Step 3 can be repeated for a maximum of iterations k<└1/δ┘−i, while satisfying the constraint p_{o,i}>p_{o,i-1}, i=2, . . . , L, which is required to meet power constraint (iii).

### Step 5

When L is even, a total of └L/2 ┘ power allocation operations are performed. The final power allocation operation, i.e., the └L/2┘-th operation, is conducted between the L+1−└L/2 ┘-th level and the └L/2 ┘-th level. For example, when L=4, the final power allocation operation is performed between the third level and the second level, obtaining the locally optimal power vector pₒ=[p_{o,1}, p_{o,2}, . . . , p_{o,L}]. The PIA optimization process is completed.

When L is odd, a total of ┌L/2┐ power allocation operations are performed. The first (i=1, 2, . . . , └L/2┘) power allocation operations follow the same procedure as when L is even (similarly, executing steps 2 to 4, and the specific power values may differ). For instance, the penultimate power allocation operation, i.e., the └L/2 ┘-th power allocation operation, is similar to that when L is even and is also conducted between the L+1−└L/2 ┘-th level and └L/2 ┘-th level. The final power allocation operation, i.e., the ┌L/2┐-th power allocation operation, is performed between the initial power p_{┌L/}2┐ of the ┌L/2┐-th level and the locally optimal power p_{o,1} of the first level, following steps 3 and 4. It should be noted that since the power of the first level is already increased during the first power allocation operation, it is further increased on the basis of the locally optimal power p_{o,1}. After completing the ┌L/2┐-th power allocation operation, the locally optimal power vector pₒ=[p_{o,1}, p_{o,2}, . . . , p_{o,L}] is similarly obtained, thereby completing the PIA optimization process. Taking L=3 as an example, steps 2 to 4 are first performed between the third level and the first level, followed by the ┌L/2┐=2-th power allocation operation between the second level and the first level, with the operational steps being steps 3 to 4.

### Step 104

Transmission signals corresponding to the multi-dimensional sparse codewords are transmitted according to the locally optimal power vector.

It should be noted that in the transmitter, the multi-dimensional sparse codewords of all users are superimposed to form the transmission signals. Therefore, after completing the transmission power allocation for each user, the transmission signals can be sent to the receiver via a Rayleigh fading channel as the medium, in accordance with the locally optimal power vector.

### Step 105

SCMA detection and power-oriented decoding are sequentially performed for users of each level, and decoded bit sequences for the L levels are output.

Step 105 includes the following sub-steps (1051)-(1055).

(1051) At the receiver, the initial LLR sequences for the received signal corresponding to the transmission signal associated with each level are calculated.

(1052) At the SCMA detector, the extrinsic interleaved LLR sequences are calculated using the log-MPA based on the initial LLR sequences.

(1053) At the PLDPC decoder, the extrinsic interleaved LLR sequences of the first level are deinterleaved and decoded using the belief propagation algorithm to output the decoded bit and the first-level extrinsic LLR sequences of the first level.

(1054) The first-level extrinsic LLR sequences are interleaved to obtain the new initial LLR sequences of the first level, and the new extrinsic interleaved LLR sequences are calculated using the log-MPA based on each new initial LLR sequence in the SCMA detector.

(1055) The extrinsic interleaved LLR sequences of the next level are deinterleaved and decoded using the belief propagation algorithm, until decoded bits of the L levels are output and formed into the decoded bit sequences.

Optionally, sub-step (1051) includes: performing the logarithmic operation on a reciprocal of a modulation order of the transmission signal associated with each level at the receiver to determine the initial LLRs for the received signal corresponding to the transmission signal, and constructing the initial LLR sequences using each initial LLR.

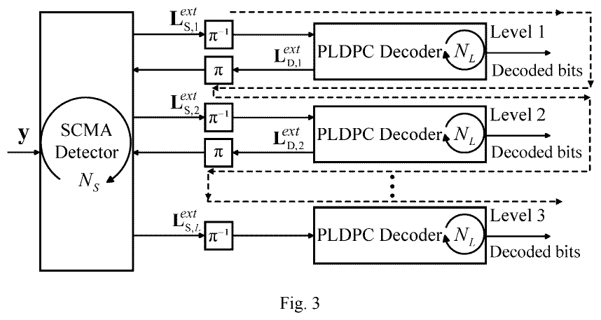

It should be noted that FIG. 3 illustrates the block diagram of the power-oriented MLD receiver in this embodiment. It can be understood that MLD, widely used in multi-data-stream systems, is a sequential decoding scheme. The currently decoded data stream can improve the decoding performance of subsequent data streams.

As a multi-user NOMA technology, the SCMA system inherently possesses multi-data-stream characteristics, making it highly suitable for integration with MLD. The power-oriented decoding approach-decoding different levels in descending order of power—can effectively address the problem of inter-user interference.

In FIG. 3, y denotes the received signal, and N_{S} and N_{L} represent the maximum iteration counts for the SCMA detector and the PLDPC decoder, respectively. The dashed line indicates the decoding order for all Z users across different levels.

Upon receiving the received signal, the SCMA detector calculates the initial LLR for the received signal corresponding to the transmission signal associated with each level. Since this embodiment employs the log-MPA algorithm and assumes equal probability for all users in selecting multi-dimensional sparse codewords as transmission signals, calculation is performed via channel initialization to determine LLR=log(1/M), where M is the modulation order. This modulation order can be understood as the codebook size. Since the codebook sizes for all users are uniform within the same SCMA system, the modulation orders are also equal for all users. Subsequently, the corresponding LLRs are organized into the initial LLR sequences Lᵢₙᵢ according to the level. Then, using the log-MPA algorithm, the extrinsic interleaved LLR sequences

$${L}_{S , n}^{ext}$$

are computed from each initial LLR sequence, where n∈{1, 2, . . . , L}.

In the designed receiver, after the SCMA detector completes the first round of detection, users at the first level with the highest power execute decoding to obtain decoded bits. Specifically, the extrinsic interleaved LLR sequences

$${L}_{S , 1}^{ext}$$

of the first level are first deinterleaved by the deinterleaver π⁻¹. Then, the PLDPC decoder employs the belief propagation (BP) algorithm for decoding and outputting the decoded bits and the first-level extrinsic LLR sequences

$${L}_{D , 1}^{e x t}$$

of the first level. Subsequently, the first-level extrinsic LLR sequences are interleaved by the interleaver π to generate new initial LLR sequences

$${L}_{ini}^{1}$$

for the first level.

Since the first SCMA detection lacks the previous iteration gains from the receiver, users at the highest-power level decode first to obtain more accurate initial LLR sequences compared to users at other levels. Therefore, the new initial LLR sequences obtained after decoding the first level, together with the initial LLR sequences

$$( {L}_{ini}^{n} , n = 2 , … , L )$$

of other levels, are sent into the SCMA detector for the second round of detection. The log-MPA algorithm is applied again to compute new extrinsic interleaved LLR sequences

$${L}_{S , n}^{ext}$$

for all levels. Subsequently, the users at the second highest power level perform BP decoding. Similarly, after deinterleaving and decoding the extrinsic interleaved LLR sequences

$${L}_{S , 2}^{ext}$$

of the second level, the decoded bits and the extrinsic LLR sequences

$${L}_{D , 2}^{ext}$$

of the second level are output. The second-level extrinsic LLR sequences are then interleaved to generate the second-level new initial LLR sequences

$${L}_{i n i}^{2} .$$

The new initial LLR sequences

$${L}_{i n i}^{2} ,$$

along with

$${L}_{i n i}^{1}$$

and the initial LLR sequences

$${L}_{ini}^{= n} ,$$

n=3, . . . , L of other levels, are used to compute new extrinsic interleaved LLR sequences via the log-MPA algorithm.

Following the above process, when the lowest-power level user completes BP decoding and outputs decoded bits for all L levels to form the decoded bit sequences, thereby completing the power-oriented MLD at the receiver. While the highest-power level users benefit from the performance gain due to their elevated power, all users at the other levels (i=2, . . . , L) achieve significant performance gains from the power-oriented MLD receiver scheme described above.

To clearly illustrate the technical effects of the PI-MLD scheme for SCMA provided in this embodiment, simulations were conducted on the PI-MLD SCMA system (PI-MLD-SCMA system) implemented in this embodiment and the traditional PLDPC-encoded SCMA system.

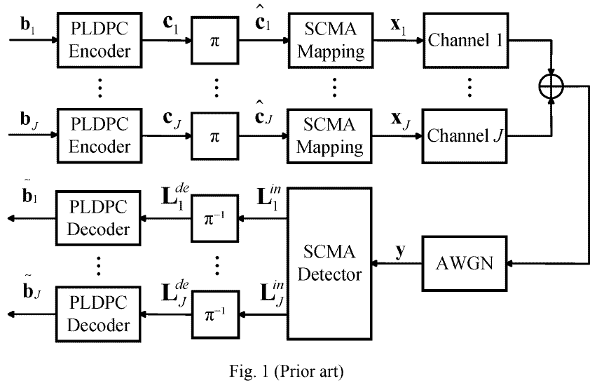

For the traditional PLDPC-coded SCMA system, no level classification was performed, the power of all users was set to 1. The traditional receiver shown in FIG. 1 was adopted. Both systems utilized the punctured PLDPC codes designed for encoding. The base matrix Bₚᵣₒ of the PLDPC code was shown below:

$${B}_{pro} = [ \begin{matrix}0 & 2 & 1 & 1 & 1 & 1 & 1 \\ 0 & 1 & 2 & 2 & 0 & 0 & 1 \\ 1 & 2 & 0 & 0 & 0 & 0 & 0 \\ 0 & 2 & 0 & 0 & 2 & 1 & 0\end{matrix} ] .$$

The second column with the highest degree distribution in the base matrix was punctured. The information bit length for each user was 1200, and the code rate was 1/2. Simulations for both SCMA systems were conducted under Rayleigh fading channels. The SCMA systems employed included scales of 4 resources×6 users and 5 resources×10 users. The 4×6 SCMA system used SCMA codebook-1 and codebook-2, while the 5×10 SCMA system used SCMA codebook-3 and codebook-4, with the modulation order for all being M=4.

Through the search process of the progressive multi-level power optimization algorithm, the locally optimal power vector for codebook-1 was obtained as pₒ₁=[1.375,0.950,0.675], for codebook-2 as pₒ₂=[1.375,0.950,0.675], for codebook-3 as pₒ₃=[1.375,0.625], and for codebook-4 as pₒ₄=[1.375,0.625]. The SCMA detector employed the log-MPA algorithm with a maximum iteration count of N_{S}=5, and the PLDPC decoding used the BP algorithm with a maximum iteration count of N_{L}=50.

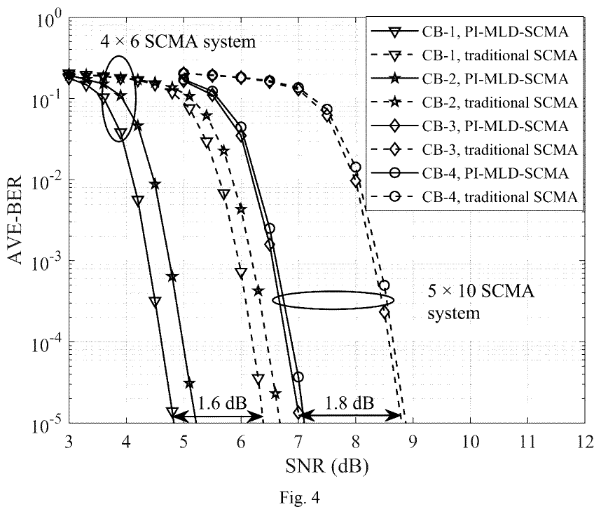

FIG. 4 showed AVE-BER performance comparison between the PI-MLD-SCMA system and the traditional SCMA system using codebooks 1-4 and their corresponding locally optimal power vectors pₒ₁□pₒ₄ in both 4×6 and 5×10 SCMA systems. It could be observed that in simulations across four different codebooks for two SCMA systems of 4×6 and 5×10, the PI-MLD-SCMA system with locally optimal power vectors achieve a gain of over 1.6 dB compared to the traditional system, demonstrating a significant improvement in system performance.

In the present disclosure, the factor graph matrix clearly reveals the mapping relationship between users and resources to enable level classification of all users. Under the premise of maintaining constant total transmission power, PIA is performed for each level to obtain the locally optimal power vector. Power-imbalanced characteristics are then leveraged for power-oriented decoding. Combining power imbalance with MLD further mitigates inter-user interference, thereby reducing the BER of the PLDPC-coded SCMA system.

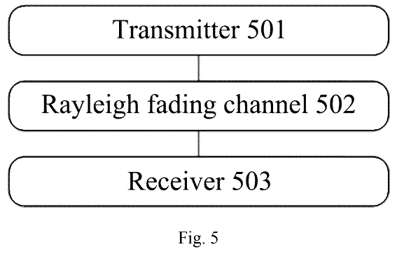

Referring to FIG. 5, a block diagram of the PI-MLD system for SCMA is provided in this embodiment.

The PI-MLD system for SCMA includes the transmitter 501, the Rayleigh fading channel 502, and the receiver 503.

The transmitter 501 is configured for generating to-be-encoded information bits of all users, and encoding the to-be-encoded information bits via the PLDPC encoder; mapping encoded bits from all users to multi-dimensional sparse codewords via predetermined codebooks, constructing the factor graph matrix using each predetermined codebook, and classifying all users into L levels based on the factor graph matrix under the predetermined constraints; based on the predetermined total transmission power, performing the PIA for all users according to the L levels using the progressive multi-level power optimization algorithm to determine the locally optimal power vector. L is a positive integer greater than 1.

The Rayleigh fading channel 502 is configured for transmitting transmission signals corresponding to the multi-dimensional sparse codewords according to the locally optimal power vector.

The receiver 503 is configured for sequentially performing SCMA detection and the power-oriented decoding for users of each level, and outputting decoded bit sequences for the L levels.

The predetermined constraints include: the number of users contained in each level must be equal; and within each level, all resources are multiplexed, and each resource is multiplexed by an identical number of users.

Optionally, based on the predetermined total transmission power, the progressive multi-level power optimization algorithm is employed to perform PIA for all users according to the Z levels, thereby determining the locally optimal power vector.

The step of determining the locally optimal power vector includes the following sub-steps.

At the transmitter 501, after performing equal-power initialization of the initial power of each user based on the predetermined total transmission power, and the transmission signal propagates through the Rayleigh channel fading, mutual information is calculated for each user based on their respective initial power using the PEXIT algorithm at the receiver 503.

The mean operation is performed on the mutual information to output the initial AMI, and the initial AMI is assigned to the old AMI.

When performing the (i=1)-th power allocation according to the power unit step size of δ, the initial power of the (L+1−i)-th level is decreased by δ×(┌L/2┐−i), and the initial power of the i-th level is increased by δ×(┌L/2┐−i), so as to determine the monotonic initialization power of the (L+1−i)-th level and the monotonic initialization power of the i-th level. δ is a positive number.

Based on the PEXIT algorithm, monotonic initialization AMI corresponding to the (L+1−i)-th level and the i-th level is determined using the monotonic initialization powers of the (L+1−i)-th level and the i-th level.

When the monotonic initialization AMI is greater than the old AMI, the monotonic initialization AMI is assigned to the old AMI.

The monotonic initialization power of the (L+1−i)-th level is decreased by δ, and the monotonic initialization power of the i-th level is increased by δ, thereby determining locally optimized powers of the (L+1−i)-th level and the i-th level and counting a number of allocations k.

Based on the PEXIT algorithm, locally optimized AMI corresponding to the (L+1−i)-th level and the i-th level is determined using the locally optimized power of the (L+1−i)-th level and the locally optimized power of the i-th level.

When the locally optimized AMI is less than or equal to the old AMI, the locally optimized power of the (k−1)-th allocation is taken as the locally optimal powers of the (L+1−i)-th level and the i-th level.

If L is an even number, a next power allocation is performed according to the power unit step size of δ until └L/2 ┘ power allocations are performed, thereby determining the locally optimal powers of the L levels and forming the locally optimal power vector.

If L is an odd number, the next power allocation is performed according to the power unit step size of δ until └L/2 ┘ power allocations are performed. Then, an initial power of the ┌L/2┐-th level is decreased by δ, and the locally optimal power of the first level is increased by δ. The monotonic initialization power of the ┌L/2┐-th level and the new monotonic initialization power of the first level are output to determine the corresponding locally optimal power, and forming the locally optimal power vector from the locally optimal powers of the L levels.

Additionally, when the monotonic initialization AMI is less than or equal to the old AMI, the monotonic initialization power is adopted as the locally optimal power for both the (L+1−i)-th level and the i-th level.

Additionally, when the locally optimized AMI is greater than the old AMI, it is determined whether the number of allocations k is less than the maximum iteration count └1/δ┘−i.

If yes (the number of allocations k is less than the maximum iteration count └1/δ┘−i), the locally optimized power is set as a new monotonic initialization power, and the locally optimized AMI is set as a new old AMI. The monotonic initialization power of the (L+1−i)-th level is decreased by δ, and the monotonic initialization power of the i-th level is increased by δ, until the locally optimized AMI is less than or equal to the new old AMI.

If no (the number of allocations k is not less than the maximum iteration count └1/δ┘−i), the locally optimized power at the k-th allocation is taken as the locally optimal powers of the (L+1−i)-th level and the i-th level.

SCMA detection and power-oriented decoding are sequentially performed for users of each level, and decoded bit sequences for the L levels are output.

At the receiver, the initial LLR sequences for the received signal corresponding to the transmission signal associated with each level is calculated.

At the SCMA detector, the extrinsic interleaved LLR sequences are calculated using the log-MPA based on the initial LLR sequences.

At the PLDPC decoder, the extrinsic interleaved LLR sequences of the first level are deinterleaved and decoded using the belief propagation algorithm to output the decoded bit and the first-level extrinsic LLR sequences of the first level.

The first-level extrinsic LLR sequences are interleaved to obtain the new initial LLR sequences of the first level, and the new extrinsic interleaved LLR sequences are calculated using the log-MPA based on each new initial LLR sequence in the SCMA detector.

The extrinsic interleaved LLR sequences of the next level are deinterleaved and decoded using the belief propagation algorithm, until decoded bits of the L levels are output and formed into the decoded bit sequences.

Optionally, the step of calculating the initial LLR sequences for the received signal corresponding to the transmission signal associated with each level includes: performing the logarithmic operation on the reciprocal of the modulation order of the transmission signal associated with each level at the receiver to determine the initial LLRs for the received signal corresponding to the transmission signal, and constructing the initial LLR sequences using each initial LLR.

The disclosure provides a computer device including a memory and a processor. The memory stores a computer program. When executed by the processor, the computer program performs the steps of the PI-MLD method described above.

The disclosure provides a computer-readable storage medium storing computer program/instructions. The computer program/instructions are configured to be executed by a processor to implement the PI-MLD method described above.

The disclosure provides a computer program product, including computer program/instructions. The computer program/instructions are configured to be executed by a processor to implement the PI-MLD method described above.

Those skilled in the art may clearly understand that, for the convenience and brevity of the description, the specific operational processes of the systems and units described above may refer to the corresponding processes in the aforementioned method embodiments and are not repeated herein.

In the several embodiments provided herein, it should be understood that the disclosed systems and methods may be implemented in other ways. For example, the system embodiments described above are merely illustrative. The division of units is only based on logical functions. In practice, there may be other divisional manners. For instance, multiple units or components may be combined or integrated into another system, or some features may be omitted or not executed. Furthermore, the interconnections or direct coupling or communication connections shown or discussed may be indirect through some interfaces, systems, or units, and may be electrical, mechanical, or other forms.

The units described as separate components may or may not be physically separated. The components displayed as units may or may not be physical units, i.e., they may be located in one place or distributed across multiple network units. Some or all of the units may be selected according to actual needs to achieve the objectives of the embodiments.

In addition, the functional units in the various embodiments may be integrated into one processing unit, or each unit may exist physically separately, or two or more units may be integrated into one unit. The integrated units described above may be implemented in the form of hardware or software functional units.

If the integrated units are implemented as software functional units and sold or used as independent products, they may be stored on a computer-readable storage medium. Based on this understanding, the technical solution of the present invention-essentially, the portion contributing to the prior art or the entirety/part of this technical solution—can be embodied as a software product. This computer software product is stored on a storage medium and includes several instructions enabling a computer device (such as a personal computer, server, or network device) to execute all or part of the steps described in the various embodiments. The aforementioned storage media includes USB flash drives, portable hard drives, read-only memory (ROM), random access memory (RAM), magnetic disks, optical discs, and other media capable of storing program code.

Described above are merely preferred embodiments of the disclosure, which are not intended to limit the disclosure. It should be understood that any modifications and replacements made by those skilled in the art without departing from the spirit of the disclosure should fall within the scope of the disclosure defined by the appended claims.

What is claimed is:

1. A power-imbalanced multi-level decoding method for sparse code multiple access (SCMA), comprising:
(a) mapping information bits from all users to multi-dimensional sparse codewords via predetermined codebooks;
(b) constructing a factor graph matrix using each predetermined codebook, and classifying all users into L levels based on the factor graph matrix under a predetermined constraint, wherein L is a positive integer greater than 1;
(c) based on a predetermined total transmission power, performing a power-imbalanced allocation for all users according to the L levels using a progressive multi-level power optimization algorithm to determine a locally optimal power vector;
(d) transmitting a transmission signal corresponding to the multi-dimensional sparse codewords according to the locally optimal power vector; and
(e) sequentially performing a power-oriented decoding for users of each level, and outputting decoded bit sequences for the L levels.

2. The power-imbalanced multi-level decoding method of claim 1, wherein the predetermined constraint comprises:
a number of users in each level must be equal; and
each resource within each level is multiplexed, and each resource is multiplexed by a same number of users.

3. The power-imbalanced multi-level decoding method of claim 1, wherein the step (c) comprises:
(c1) performing an equal-power initialization on an initial power of each user based on the predetermined total transmission power, and then calculating mutual information based on the initial power of each user using a protograph extrinsic information transfer (PEXIT) algorithm;
(c2) performing a mean operation on the mutual information to output an initial average mutual information, and assigning the initial average mutual information to an old average mutual information;
(c3) when performing a (i=1)-th power allocation according to a power unit step size of δ, decreasing an initial power of a (L+1−i)-th level by δ× (┌L/2┐−i) and increasing an initial power of an i-th level by δ×(┌L/2┐−i), so as to determine a monotonic initialization power of the (L+1−i)-th level and a monotonic initialization power of the i-th level; wherein δ is a positive number;
(c4) based on the PEXIT algorithm, determining monotonic initialization average mutual information corresponding to the (L+1−i)-th level and the i-th level using the monotonic initialization power of the (L+1−i)-th level and the monotonic initialization power of the i-th level;
(c5) when the monotonic initialization average mutual information is greater than the old average mutual information, assigning the monotonic initialization average mutual information to the old average mutual information;
(c6) decreasing the monotonic initialization power of the (L+1−i)-th level by δ; increasing the monotonic initialization power of the i-th level by δ; and determining a locally optimized power of the (L+1−i)-th level and a locally optimized power of the i-th level, and counting a number of allocations k;
(c7) based on the PEXIT algorithm, determining locally optimized average mutual information corresponding to the (L+1−i)-th level and the i-th level using the locally optimized power of the (L+1−i)-th level and the locally optimized power of the i-th level; and
(c8) when the locally optimized average mutual information is less than or equal to the old average mutual information, taking a locally optimized power of a (k−1)-th allocation as locally optimal powers of the (L+1−i)-th level and the i-th level;
wherein if L is an even number, performing a next power allocation according to the power unit step size of δ until └L/2┘ power allocations are performed, and thereby determining locally optimal powers of the L levels and forming a locally optimal power vector; and
if L is an odd number, performing a next power allocation according to the power unit step size of δ until └L/2 ┘ power allocations are performed; decreasing an initial power of a ┌L/2┐-th level by δ, and increasing a locally optimal power of a first level by δ; outputting a monotonic initialization power of the ┌L/2┐-th level and a new monotonic initialization power of the first level to determine a corresponding locally optimal power, and forming the locally optimal power vector from locally optimal powers of the L levels.

4. The power-imbalanced multi-level decoding method of claim 3, further comprising:
when the locally optimized average mutual information is greater than the old average mutual information, determining whether the number of allocations k is less than a predetermined maximum iteration count └1/δ┘−i;
if yes, setting the locally optimized power as a new monotonic initialization power and setting the locally optimized average mutual information as a new old average mutual information, decreasing the new monotonic initialization power of the (L+1−i)-th level by δ, and increasing the new monotonic initialization power of the i-th level by δ, until the locally optimized average mutual information is less than or equal to the new old average mutual information; and
if no, a locally optimized power at the k-th allocation is taken as locally optimal powers of the (L+1−i)-th level and the i-th level.

5. The power-imbalanced multi-level decoding method of claim 1, wherein the step (e) comprises:
(e1) calculating initial log-likelihood ratio (LLR) sequences for a received signal corresponding to the transmission signal associated with each level;
(e2) calculating extrinsic interleaved LLR sequences using a log-domain message passing algorithm based on the initial LLR sequences;
(e3) deinterleaving the extrinsic interleaved LLR sequences of a first level, and performing a decoding using a belief propagation algorithm to output decoded bit sequences and a first-level extrinsic LLR sequences of the first level;
(e4) interleaving the first-level extrinsic LLR sequences to obtain new initial LLR sequences of the first level, and calculating new extrinsic interleaved LLR sequences using the log-domain message passing algorithm based on each new initial LLR sequence; and
(e5) deinterleaving extrinsic interleaved LLR sequences of a next level, and performing decoding using the belief propagation algorithm, until decoded bits of the L levels are output and formed into the decoded bit sequences.

6. The power-imbalanced multi-level decoding method of claim 5, wherein the step (e1) comprises:
performing a logarithmic operation on a reciprocal of a modulation order of the transmission signal associated with each level to determine the initial LLR for the received signal corresponding to the transmission signal; and
constructing the initial LLR sequences using each initial LLR.

7. A power-imbalanced multi-level decoding system for SCMA, comprising:
a transmitter;
a Rayleigh fading channel; and
a receiver;
the transmitter is configured for mapping information bits of all users to multi-dimensional sparse codewords via predetermined codebooks; constructing a factor graph matrix using each predetermined codebook, and classifying all users into L levels based on the factor graph matrix under a predetermined constraint, wherein L is a positive integer greater than 1; based on a predetermined total transmission power, performing a power-imbalanced allocation for all users according to the L levels using a progressive multi-level power optimization algorithm to determine a locally optimal power vector;
the Rayleigh fading channel is configured for transmitting a transmission signal corresponding to the multi-dimensional sparse codewords according to the locally optimal power vector; and
the receiver is configured for sequentially performing a power-oriented decoding for users of each level, and outputting decoded bit sequences for the L levels.

8. A computer device, comprising:
a memory; and
a processor;
wherein the memory is configured to store a computer program; and the computer program is configured to be executed by a processor to implement the power-imbalanced multi-level decoding method according to claim 1.

9. A computer-readable storage medium, wherein a computer program/instruction is stored on the computer-readable storage medium, and the computer program/instruction is configured to be executed by a processor to implement the power-imbalanced multi-level decoding method according to claim 1.

10. A computer program product, comprising:
a computer program/instruction;
wherein the computer program/instruction is configured to be executed by a processor to implement the power-imbalanced multi-level decoding method according to claim 1.
